(19) United States
(12) Patent Application Publication
(10) Pub. No.: US 2014/0087527 A1
(43) Pub. Date: Mar. 27, 2014

(54) METHOD OF FORMING THIN FILM POLY SILICON LAYER AND METHOD OF FORMING THIN FILM TRANSISTOR

(71) Applicant: WINTEK CORPORATION, Taichung City (TW)

(72) Inventors: Hieng-Hsiung Huang, Hsinchu City (TW); Wen-Chun Wang, Taichung City (TW); Heng-Yi Chang, Taipei City (TW); Chin-Chang Liu, Taichung City (TW)

(73) Assignee: WINTEK CORPORATION, Taichung City (TW)

(21) Appl. No.: 14/035,930

(22) Filed: Sep. 24, 2013

(30) Foreign Application Priority Data
Sep. 25, 2012 (TW) 101135117

(51) Int. Cl. H01L 29/786

(52) U.S. Cl. CPC H01L 29/78678; H01L 29/78669
USPC 438/158

(57) ABSTRACT

A method of forming a thin film poly silicon layer includes following steps. Firstly, a substrate is provided. A thin film silicon layer is then formed on the substrate by a silicon thin film deposition process. A heating treatment is then applied to the substrate so as to convert the thin film silicon layer into a thin film poly silicon layer. A method of forming a thin film transistor includes following steps. A first patterning process is performed on the thin film poly silicon layer on the substrate to form a semiconductor pattern. Subsequently, a gate insulation layer, a gate electrode, a source electrode and a drain electrode are formed.

### BACKGROUND OF THE INVENTION

1. Field of the Invention

The present invention relates to a method of forming a thin film poly silicon layer and a method of forming a thin film transistor, and more particularly, to a method of forming a thin film poly silicon layer and a method of forming a thin film transistor wherein a thin film silicon layer is formed on a substrate first, and the thin film silicon layer is then converted into a thin film poly silicon layer by thermal annealing.

2. Description of the Prior Art

In recent years, applications of flat display devices are rapidly developed. Electronics, such as televisions, cell phones, mobiles, and refrigerators, are installed with flat display devices. A thin film transistor (TFT) is a kind of semiconductor devices commonly used in the flat display device, such as a liquid crystal display (LCD), an organic light emitting diode (OLED) display, and an electronic paper (E-paper).

The thin film transistors in current display industries mainly include amorphous silicon thin film transistors (a-Si TFTs) and poly silicon thin film transistors. The amorphous silicon thin film transistor is currently the mainstream thin film transistor applied in the display industry because of its mature process techniques and high yield. However, the amorphous silicon thin film transistor may not be good enough to satisfy requirements of foreseeable high performance display devices, because the electrical mobility of the amorphous silicon thin film transistor, which is mainly determined by material properties of amorphous silicon, can not be effectively improved by process tuning or design modification. The electrical mobility of the poly silicon thin film transistor is much better because of material properties of poly silicon. In a conventional method of forming a thin film poly silicon layer, an amorphous silicon layer is formed and a thin film poly silicon layer may be obtained after crystallizing the amorphous silicon layer by high temperature or high energy treatments such as laser annealing. However, the crystallization process after the film deposition has several disadvantages such as longer process time, higher cost, and lower manufacturing efficiency. In addition, the uniformity of the crystallization process on a large size substrate is still a problem needed to be solved, and the conventional method of forming the thin film poly silicon layer is accordingly limited to specific products and applications.

### SUMMARY OF THE INVENTION

It is one of the objectives of the present invention to provide a method of forming a thin film poly silicon layer and a method of forming a thin film transistor. A thin film silicon layer is formed on a substrate. A heating treatment is then performed to convert the thin film silicon layer into a thin film poly silicon layer by thermal annealing. The thin film poly silicon layer is then used to form a thin film transistor.

To achieve the purposes described above, a preferred embodiment of the present invention provides a method of forming a thin film poly silicon layer. The method of forming the thin film poly silicon layer includes following steps. Firstly, a substrate is provided. A thin film silicon layer is then formed on the substrate by a silicon thin film deposition process. A heating treatment is then applied to the substrate so as to convert the thin film silicon layer into a thin film poly silicon layer.

To achieve the purposes described above, a preferred embodiment of the present invention provides a method of forming a thin film transistor. The method of forming the thin film transistor includes following steps. Firstly, a substrate is provided. A thin film silicon layer is then formed on the substrate by a silicon thin film deposition process. A heating treatment is then applied to the substrate so as to convert the thin film silicon layer into a thin film poly silicon layer. A first patterning process is performed on the thin film poly silicon layer to form a semiconductor pattern. Subsequently, a gate insulation layer, a gate electrode, a source electrode and a drain electrode are formed.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a flow chart of a method of forming a thin film poly silicon layer according to a first preferred embodiment of the present invention.

FIGS. 2-4 are schematic diagrams illustrating the method of forming the thin film poly silicon layer according to the first preferred embodiment of the present invention.

FIG. 5 is a flow chart of a method of forming a thin film transistor according to a second preferred embodiment of the present invention.

FIGS. 6-8 are schematic diagrams illustrating the method of forming the thin film transistor according to the second preferred embodiment of the present invention.

FIG. 9 is a flow chart of a method of forming a thin film transistor according to a third preferred embodiment of the present invention.

FIGS. 10-13 are schematic diagrams illustrating the method of forming the thin film transistor according to the third preferred embodiment of the present invention.

FIG. 14 is a flow chart of a method of forming a thin film transistor according to a fourth preferred embodiment of the present invention.

FIG. 15 and FIG. 16 are schematic diagrams illustrating the method of forming the thin film transistor according to the fourth preferred embodiment of the present invention.

FIG. 17 is a flow chart of a method of forming a thin film transistor according to a fifth preferred embodiment of the present invention.

FIGS. 18-20 are schematic diagrams illustrating the method of forming the thin film transistor according to the fifth preferred embodiment of the present invention.

FIG. 21 is a schematic diagram illustrating a method of forming the thin film transistor according to a sixth preferred embodiment of the present invention.

### DETAILED DESCRIPTION

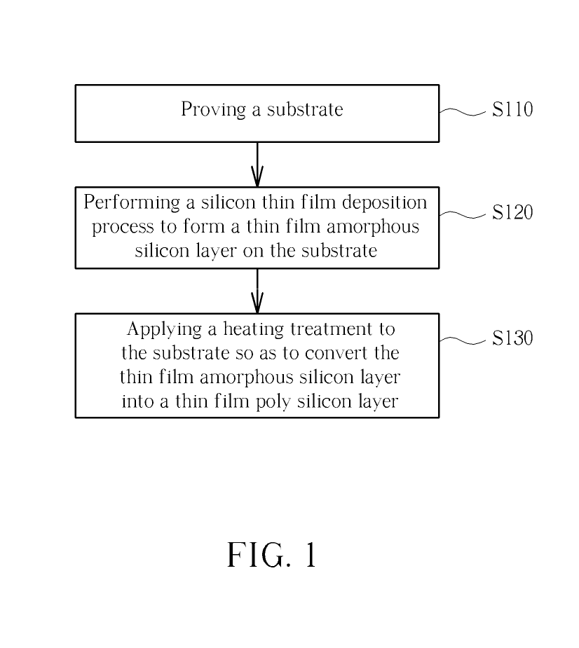

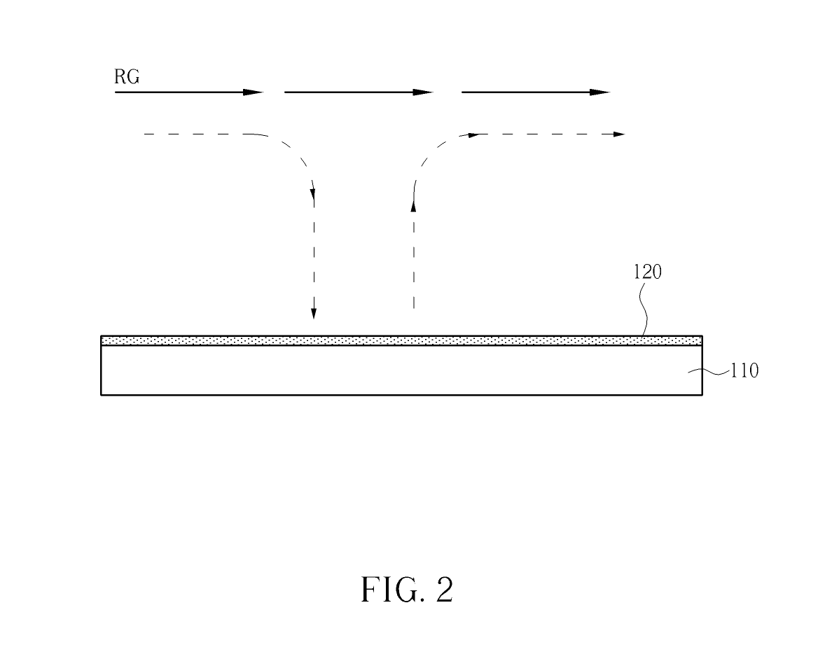

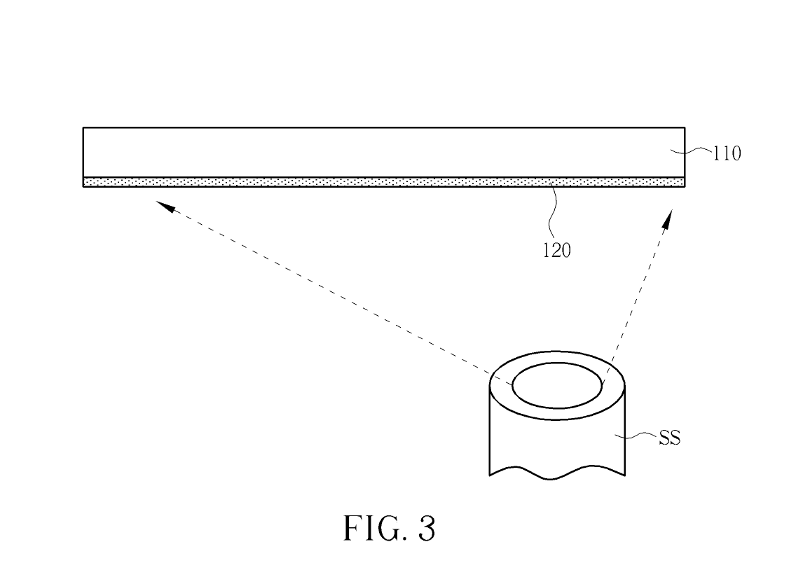

Please refer to FIGS. 1-4. FIG. 1 is a flow chart of a method of forming a thin film poly silicon layer according to a first preferred embodiment of the present invention. FIGS. 2-4 are schematic diagrams illustrating the method of forming the thin film poly silicon layer according to this embodiment. Please note that the figures are only for illustration and the figures may not be to scale. The scale may be further modified according to different design considerations. As shown in FIGS. 1-4, the first preferred embodiment of the present invention provides a method of forming a thin film poly silicon layer. The method of forming the thin film poly silicon layer includes the following steps. Firstly, in step S110, a substrate 110 is provided. The substrate 110 may preferably include a glass substrate, a ceramic substrate, or other substrates made of appropriate materials. Subsequently, in step S120, a thin film silicon layer 120 is then formed on the substrate 110 by a silicon thin film deposition process. For example, the thin film silicon layer is an amorphous silicon layer or a small crystal silicon layer and the grain size of the small crystal layer is smaller than 100 nm. The silicon thin film deposition process in this embodiment preferably includes a chemical vapor deposition (CVD) process (as shown in FIG. 2), a physical vapor deposition (PVD) process (as shown in FIG. 3), or other appropriate silicon thin film deposition processes. As shown in FIG. 2, in this embodiment, a reactive gaseous material RG is preferably used as a silicon source for forming the thin film silicon layer 120 on the substrate 110. The reactive gaseous material RG preferably includes silane (SiH₄) or dichlorosilane (SiH₂Cl₂). Silane or dichlorosilane may be disassociated for performing the silicon thin film deposition process on the substrate 110. It is worth noting that the above-mentioned chemical vapor deposition process may preferably include a plasma enhanced chemical vapor deposition (PECVD) process, a metal-organic chemical vapor deposition (MOCVD) process, or a low pressure chemical vapor deposition (LPCVD) process, but not limited thereto. Additionally, as shown in FIG. 3, the forming method of the thin film silicon layer 120 in this embodiment may also include using a silicon source SS such as a silicon target of a sputtering process so as to perform the silicon thin film deposition process on the substrate 110.

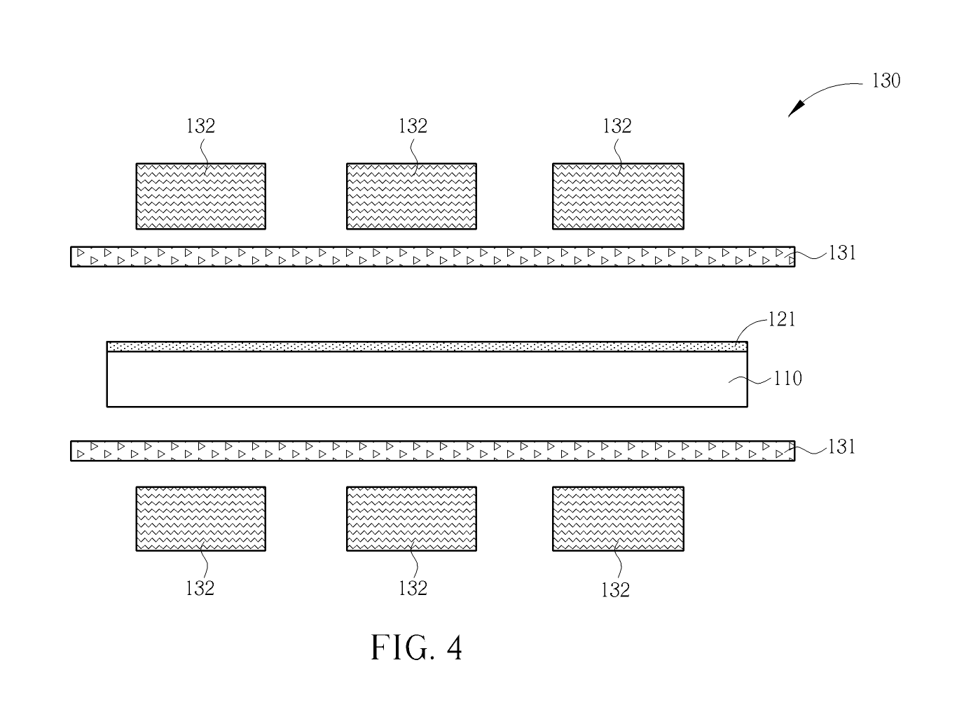

As shown in FIGS. 1-4, in step S130, a heating treatment is then applied to the substrate 110 so as to convert the thin film silicon layer 120 into a thin film poly silicon layer 121 by thermal annealing. It is worth noting that a heating temperature of the heating treatment to the substrate 110 is preferably between 650 Celsius degrees and 700 Celsius degrees, but not limited thereto. In addition, the heating treatment mentioned above may preferably include heating the substrate 110 by a heating device 130. The heating device 130 may preferably include a furnace device, a light source heating device, an ion beam heating device, an electrode beam heating device, a filament heating device, or other appropriate heating devices. A finance device is employed as the heating device 130 in this embodiment, but not limited thereto. As shown in FIG. 4, the heating device 130 may include a quartz tube 131 and a plurality of heating sources 132. Each of the heating sources 132 may include a susceptor heating source, a thermal resistance heating source, a radio frequency (RF) heating source, an infrared (IR) heating source, or other appropriate heating sources for heating the substrate 110. Because the heating treatment is performed in this embodiment to convert the thin film silicon layer 120 into the thin film poly silicon layer 121 by thermal annealing, a traditional laser annealing process will not be required in this embodiment. Therefore, the method of forming the thin film poly silicon layer in this embodiment has advantages such as lower cost, better uniformity of the thin film poly silicon layer, and better compatibility of forming the thin film poly silicon layer on large-sized substrates.

The following description will detail the different embodiments of the method of forming the thin film poly silicon layer in the present invention. To simplify the description, identical components in each of the following embodiments are marked with identical symbols.

For making it easier to understand the differences between the embodiments, the following description will detail the dissimilarities among different embodiments and the identical features will not be redundantly described.

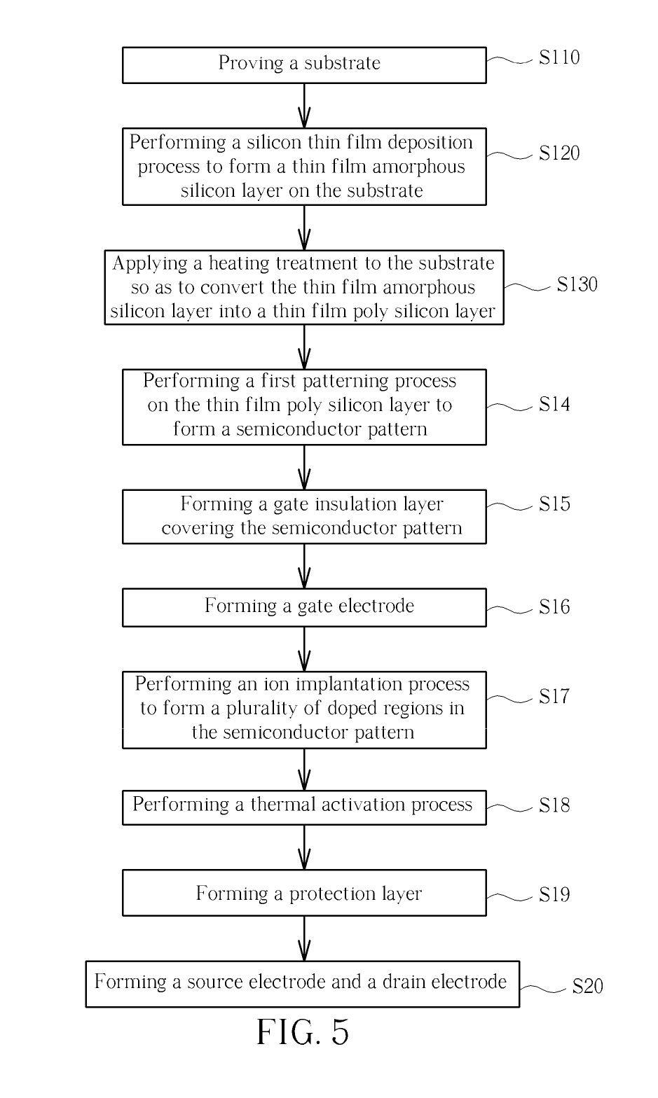

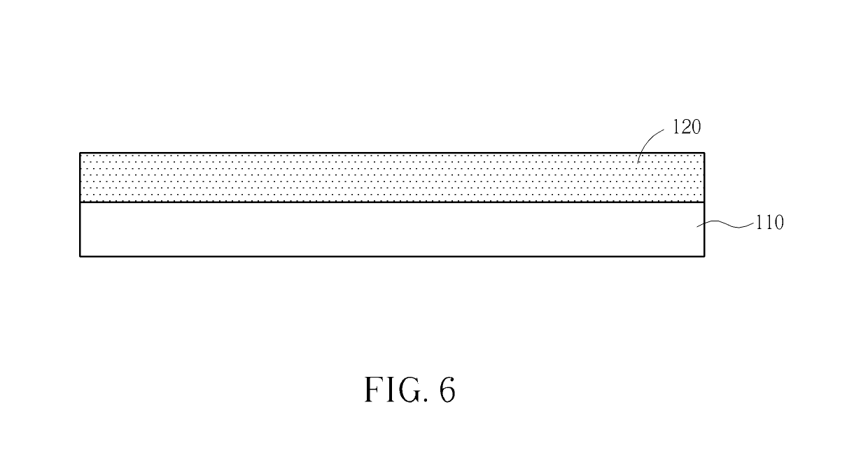

Please refer to FIGS. 5-8. FIG. 5 is a flow chart of a method of forming a thin film transistor according to a second preferred embodiment of the present invention. FIGS. 6-8 are schematic diagrams illustrating the method of forming the thin film transistor according to this embodiment. As shown in FIGS. 5-8, the second preferred embodiment of the present invention provides a method of forming a thin film transistor. The method of forming the thin film transistor includes the following steps. Firstly, in step S110, a substrate 110 is provided. Subsequently, in step S120, a thin film silicon layer 120 is then formed on the substrate 110 by a silicon thin film deposition process. The silicon thin film deposition process in this embodiment may preferably include a physical vapor deposition process, or a chemical vapor deposition process such as a plasma enhanced chemical vapor deposition process, a metal-organic chemical vapor deposition process, or a low pressure chemical vapor deposition process, but not limited thereto. The method of forming the thin film silicon layer 120 has been detailed in the first preferred embodiment and will not be redundantly described. Subsequently, in step S130, a heating treatment is then applied to the substrate 110 so as to convert the thin film silicon layer 120 into a thin film poly silicon layer 121 by thermal annealing. A heating temperature of the heating treatment to the substrate 110 is preferably between 650 Celsius degrees and 700 Celsius degrees, but not limited thereto. In the heating treatment of this embodiment, the related technical features such as types and structures of the heating device, types of the heating source, and the heating temperature setting are similar to those of the first preferred embodiment detailed above and will not be redundantly described. In other words, in the method of forming the thin film transistor in this embodiment, the step S110, the step S120, and the step S130 are preferably similar to the method of forming the thin film poly silicon layer in the first preferred embodiment, but not limited thereto.

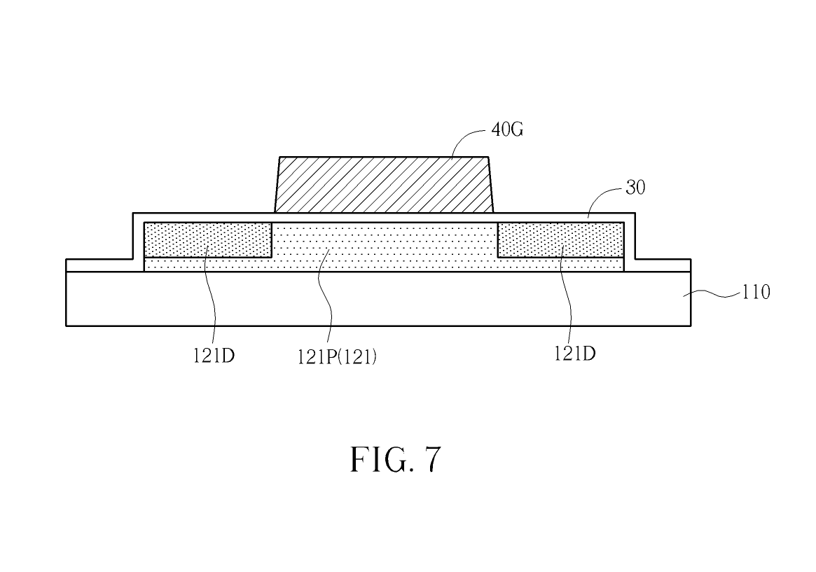

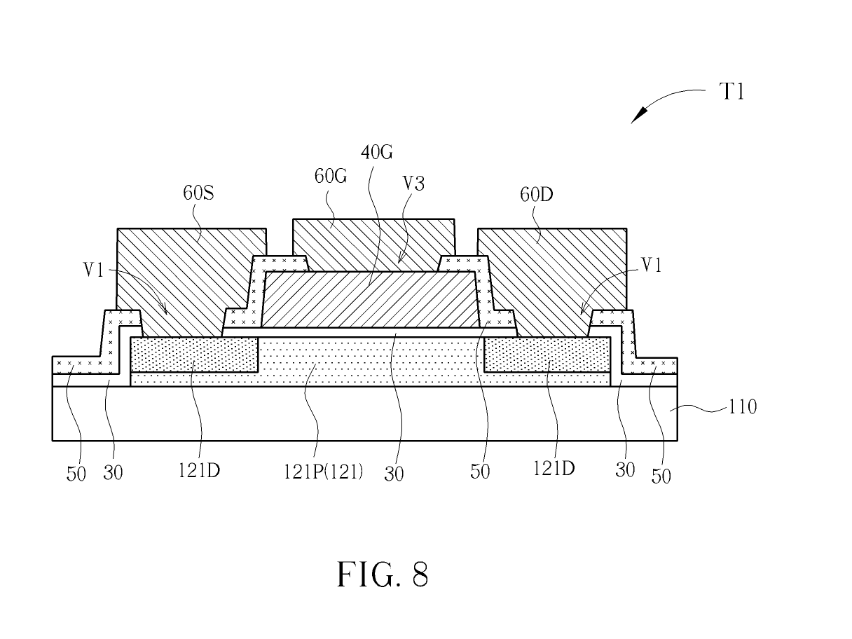

As shown in FIG. 5 and FIG. 7, in step S14, a first patterning process is then performed on the thin film poly silicon layer 121 so as to form a semiconductor pattern 121P. Subsequently, in step S15, a gate insulation layer 30 is formed to cover the semiconductor pattern 121P and the substrate 110. In step S16, a gate electrode 40G is then formed on the gate insulation layer 30. In other words, the gate insulation layer 30 in this embodiment is formed after the first patterning process, and the gate electrode 40G is formed after forming the gate insulation layer 30. Subsequently, in step S17, an ion implantation process is then performed after forming the gate electrode 40G so as to form a plurality of doped regions 121D in the semiconductor pattern 121P. It is worth noting that the doped regions 121D in this embodiment are preferably p-type doped poly silicon materials, but not limited thereto. Additionally, the gate electrode 40G may preferably be used as a shadow mask in the ion implantation process mentioned above so as to simplify the related processes and generate a self-aligned effect, but not limited thereto. In this embodiment, the method of forming the thin film transistor may further include performing a thermal activation process in step S18 after the ion implantation process in the step S17, and the thermal activation process is configured to activate the doped regions 121D. The thermal activation process may preferably include a light heating approach, an ion beam heating approach, an electrode beam heating approach, a furnace heating approach, or a filament heating approach, but not limited thereto. Subsequently, as shown in FIG. 5 and FIG. 8, in step S19, a protection layer 50 is formed on the gate insulation layer 30 and the gate electrode 40G. A plurality of first openings V1 are then formed in the protection layer 50 and the gate insulation layer 30. The first openings V1 partially expose the doped regions 121D. A source electrode 60S and a drain electrode 60D are then formed in step S20 so as to form a thin film transistor T1 in FIG. 8. In this embodiment, the source electrode 60S and the drain electrode 60D contact the doped region 121D for being electrically connected with the doped region 121D via the first openings V1. A third opening V3 may be formed in the protection layer 50 when forming the first openings V1. The third opening V3 at least partially exposes the gate electrode 40G, but not limited thereto. Additionally, in the method of forming the thin film transistor in this embodiment, an auxiliary electrode 60G may be selectively formed in the step of forming the source electrode 60S and the drain electrode 60D. The auxiliary electrode 60G may contact and be electrically connected with the gate electrode 40G via the third opening V3. In other words, the source electrode 60S, the drain electrode 60D, and the auxiliary electrode 60G may be formed simultaneously by patterning a conductive layer, but not limited thereto. In this embodiment, the thin film transistor T1 may be regarded as a top gate poly silicon thin film transistor.

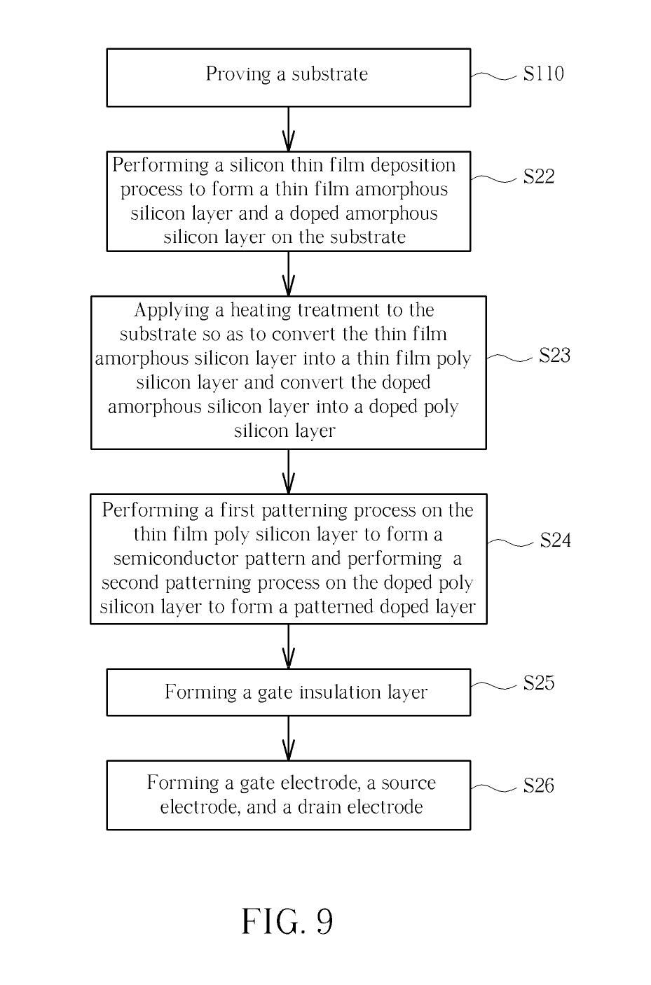

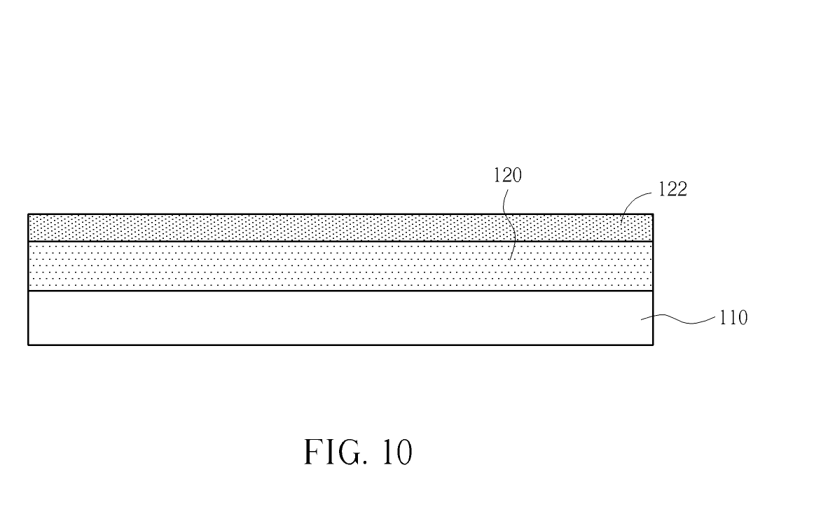

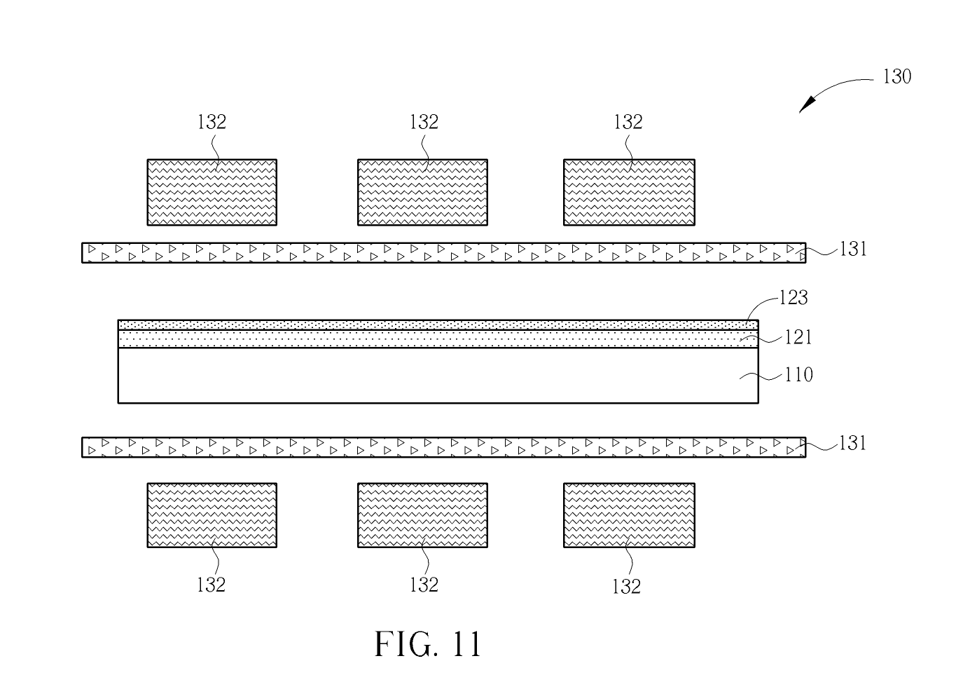

Please refer to FIGS. 9-13. FIG. 9 is a flow chart of a method of forming a thin film transistor according to a third preferred embodiment of the present invention. FIGS. 10-13 are schematic diagrams illustrating the method of forming the thin film transistor in this embodiment. As shown in FIGS. 9-13, the difference between the method of forming the thin film transistor in this embodiment and the method of the second preferred embodiment is that a thin film silicon layer 120 and a doped silicon layer 122 are formed on the substrate 110 by a silicon thin film deposition process in step S22 after the step S110. The doped silicon layer 122 in this embodiment may preferably include a p-type doped silicon material, but not limited thereto. In other words, a single silicon thin film deposition process is used in this embodiment to form the doped silicon layer 122 on the thin film silicon layer 120 so as to simplify the related process, but not limited thereto. Subsequently, as shown in FIGS. 9-11, in step S23, a heating treatment is then applied to the substrate 110 so as to convert the thin film silicon layer 120 into a thin film poly silicon layer 121, and the heating treatment is also used to covert the doped silicon layer 122 into a doped poly silicon layer 123. In the heating treatment of this embodiment, the related technical features such as types and structures of the heating device, types of the heating source, and the heating temperature setting are similar to those of the first preferred embodiment detailed above and will not be redundantly described.

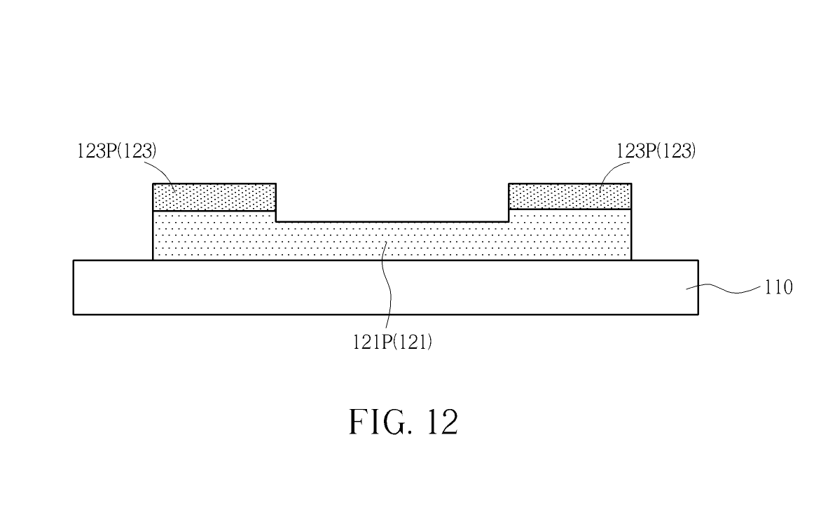

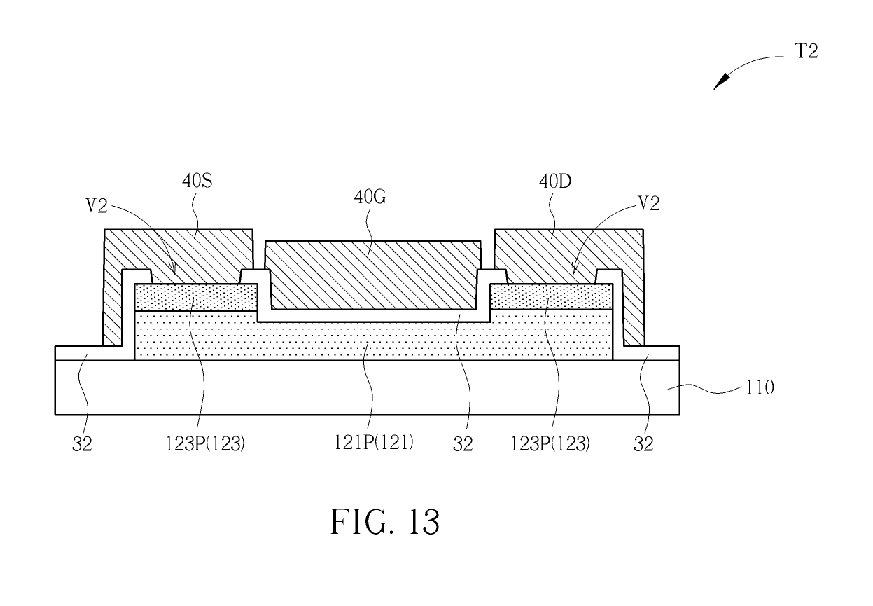

As shown in FIG. 9 and FIG. 12, in step S24, a first patterning process is then performed on the poly silicon layer 121 to form a semiconductor pattern 121P, and a second patterning process is performed on the doped poly silicon layer 123 to form a patterned doped layer 123P. In this embodiment, the first patterning process and the second patterning process are preferably integrated in one photo lithography etching process for process simplification purpose, but not limited thereto. In other preferred embodiments of the present invention, the first patterning process and the second patterning process may also be performed separately according to other considerations. As shown in FIG. 9 and FIG. 13, in step S25, a gate insulation layer 32 is formed after the second patterning process, and the gate insulation layer 32 covers the semiconductor pattern 121P and the patterned doped layer 123P. The gate insulation layer 32 may preferably include a plurality of second openings V2, and the second openings V2 are used to at least partially expose the patterned doped layer 123P. Subsequently, in step S26, a thin film transistor T2 as shown in FIG. 13 is then formed after forming a gate electrode 40G, a source electrode 40S, and a drain electrode 40D. In other words, the gate electrode 40G, the source electrode 40S, and the drain electrode 40D are formed after forming the gate insulation layer 32. The gate electrode 40G, the source electrode 40S, and the drain electrode 40D are preferably formed by one identical process step so as to simplify the process. For example, the gate electrode 40G, the source electrode 40S, and the drain electrode 40D may be simultaneously formed by patterning one conductive layer, but not limited thereto. The source electrode 40S and the drain electrode 40D contact the patterned doped layer 123P via the second openings V2. The source electrode 40S and the drain electrode 40D are electrically connected to the patterned doped layer 123P. Because the doped poly silicon layer 123 and the thin film poly silicon layer 121 may be formed by one identical silicon thin film deposition process and one identical heating treatment, an additional ion implantation process will not be required in this embodiment. The purposes of process simplification and cost reduction may be achieved accordingly.

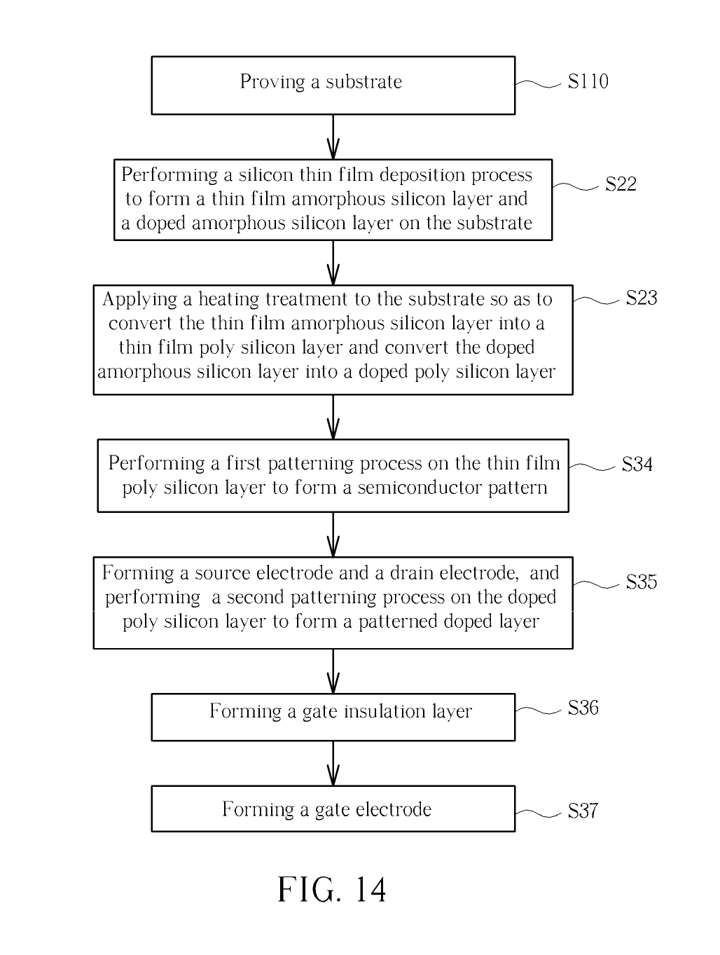

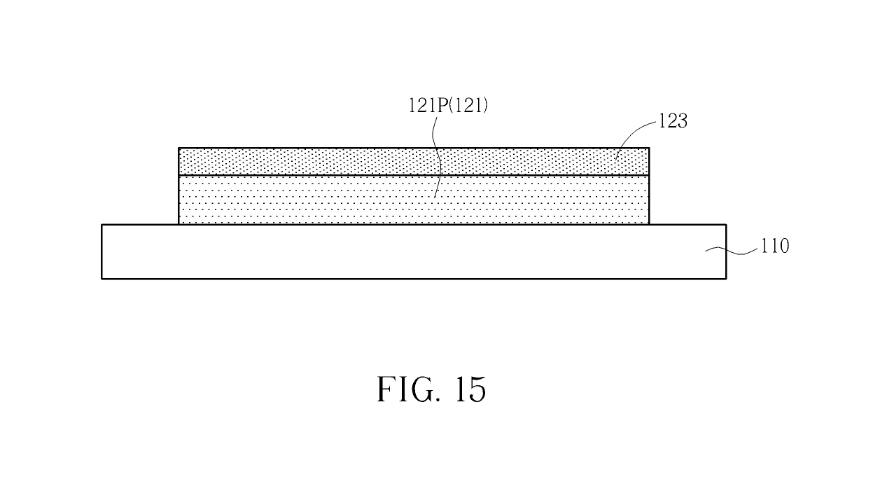

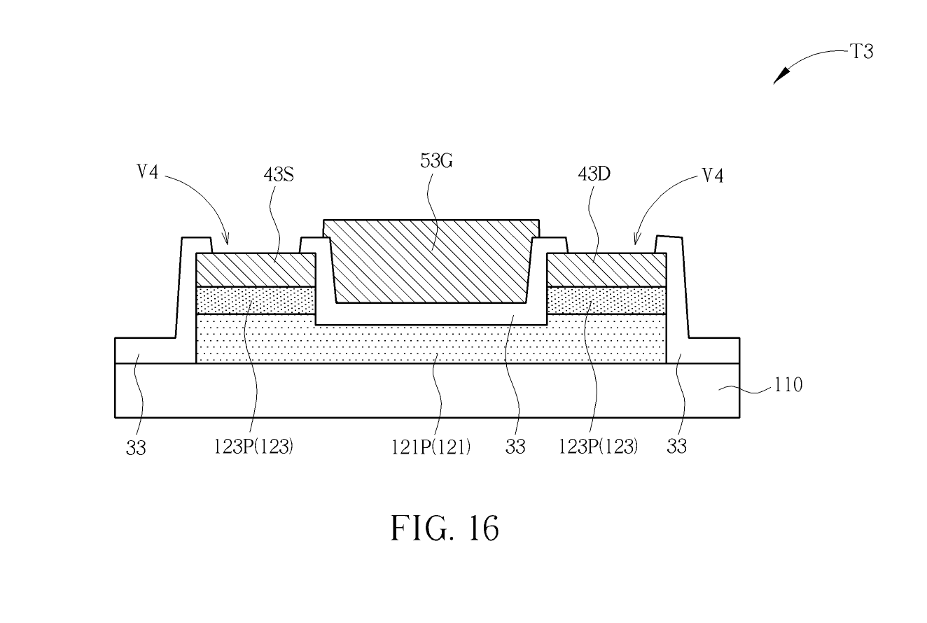

Please refer to FIGS. 14-16. FIG. 14 is a flow chart of a method of forming a thin film transistor according to a fourth preferred embodiment of the present invention. FIG. 15 and FIG. 16 are schematic diagrams illustrating the method of forming the thin film transistor in this embodiment. As shown in FIGS. 14-16, the difference between the method of forming the thin film transistor in this embodiment and the method of the third preferred embodiment is that a first patterning process is performed on a thin film poly silicon layer 121 to form a semiconductor layer 121P in step S34 after the step S23. Subsequently, in step S35, a source electrode 43S and a drain electrode 43D are formed on the doped poly silicon layer 123, and a second patterning process is then performed on the doped poly silicon layer 123 to form a patterned doped layer 123P. In this embodiment, the second patterning process and the process of forming the source electrode 43S and the drain electrode 43D are preferably integrated in one photo lithography etching process for process simplification purpose, but not limited thereto. In other words, the patterned doped layer 123P, the source electrode 43S, and the drain electrode 43D are preferably formed by an identical process step. In other preferred embodiments of the present invention, the second patterning process may also be performed after forming the source electrode 43S and the drain electrode 43D according to other considerations. The source electrode 43S and the drain electrode 43D may preferably be used as a shadow mask in the second patterning process mentioned above so as to simplify the related processes, but not limited thereto. Subsequently, in step S36, a gate insulation layer 33 is formed after the second patterning process. The gate insulation layer 33 covers the source electrode 43S, the drain electrode 43D, the patterned doped layer 123P, and the semiconductor pattern 121P. The gate insulation layer 33 includes a plurality of second openings V4, and the second openings V4 are used to at least partially expose the source electrode 43S and the drain electrode 43D. In step S37, a thin film transistor T3 as shown in FIG. 16 is formed after forming a gate electrode 53G on the gate insulation layer 33.

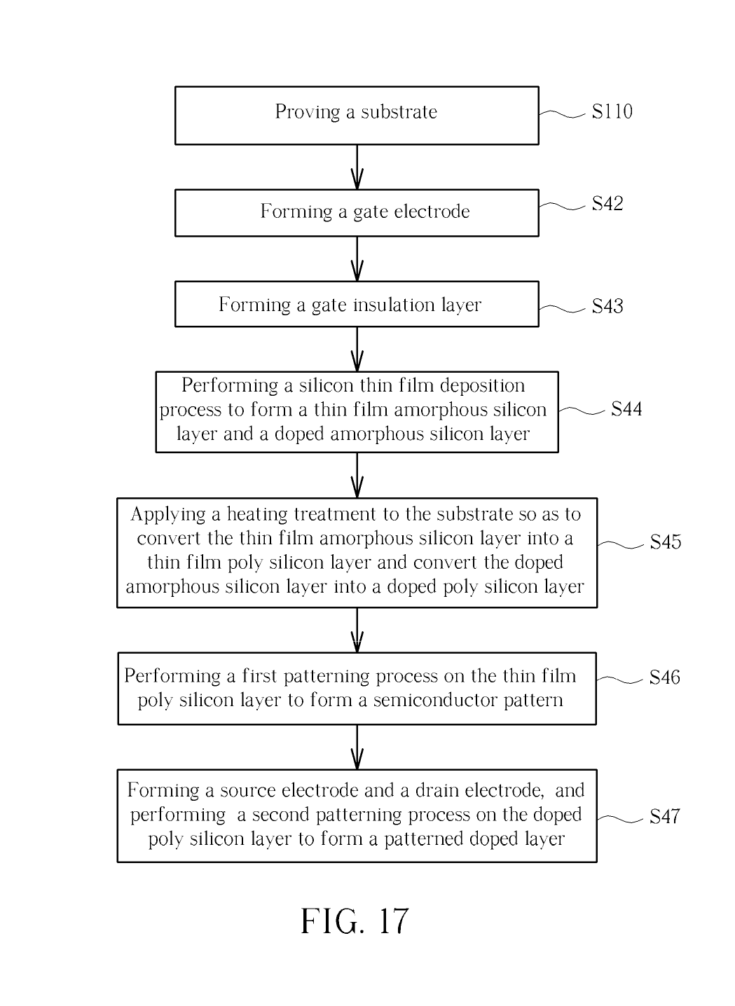

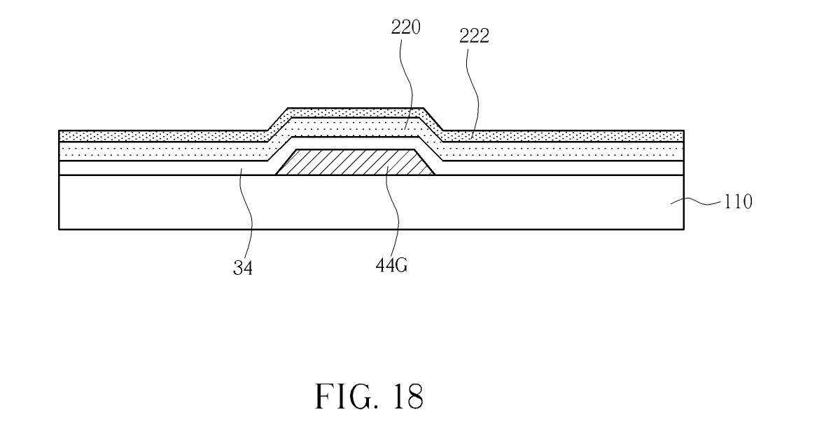

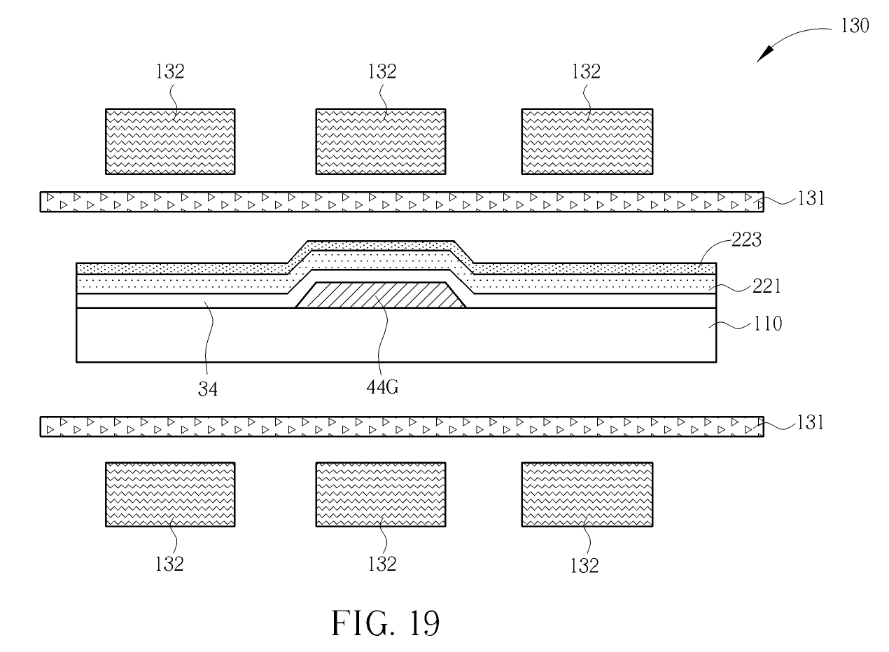

Please refer to FIGS. 17-20. FIG. 17 is a flow chart of a method of forming a thin film transistor according to a fifth preferred embodiment of the present invention. FIGS. 18-20 are schematic diagrams illustrating the method of forming the thin film transistor in this embodiment. As shown in FIGS. 17-20, the method of forming the thin film transistor in this embodiment includes the following steps. Firstly, in step S110, a substrate 110 is provided. Subsequently, in step S42, a gate electrode 44G is formed on the substrate 110. A gate insulation layer 34 is then formed in step S43, and the gate insulation layer 34 covers the gate electrode 44G and the substrate 110. In step S44, a thin film silicon layer 220 and a doped silicon layer 222 are formed on the substrate 110 by a silicon thin film deposition process. Subsequently, in step S45, a heating treatment is then applied to the substrate 110 so as to convert the thin film silicon layer 220 into a thin film poly silicon layer 221, and the heating treatment is also used to covert the doped silicon layer 222 into a doped poly silicon layer 223. In the heating treatment of this embodiment, the related technical features such as types and structures of the heating device, types of the heating source, and the heating temperature setting are similar to those of the first preferred embodiment detailed above and will not be redundantly described.

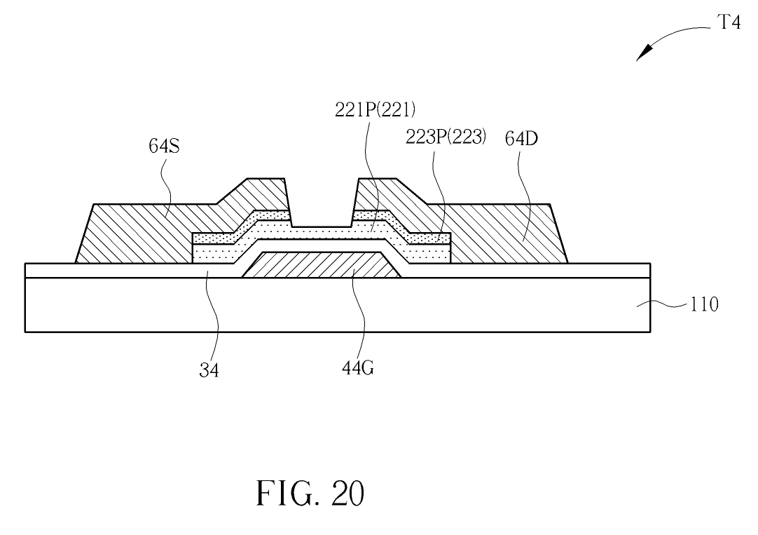

As shown in FIG. 17 and FIG. 20, a first patterning process is performed on the thin film poly silicon layer 221 to form a semiconductor layer 221P in step S46. Subsequently, in step S47, a source electrode 64S and a drain electrode 64D are formed, and a second patterning process is then performed on the doped poly silicon layer 223 to form a patterned doped layer 223P and a thin film transistor T4 as shown in FIG. 20. As shown in FIGS. 18-20, the gate electrode 44G and the gate insulation layer 34 are formed before forming the thin film silicon layer 220 and the doped silicon layer 222. The source electrode 64S and the drain electrode 64D are formed after forming the thin film poly silicon layer 221 and the doped poly silicon layer 223. The thin film transistor T4 in this embodiment may be regarded as a bottom gate poly silicon thin film transistor. It is worth noting that the patterned doped layer 223P, the source electrode 64S, and the drain electrode 64D are preferably formed by an identical process step. In other words, the second patterning process and the process of forming the source electrode 64S and the drain electrode 64D are preferably integrated in one photo lithography etching process for process simplification purpose, but not limited thereto.

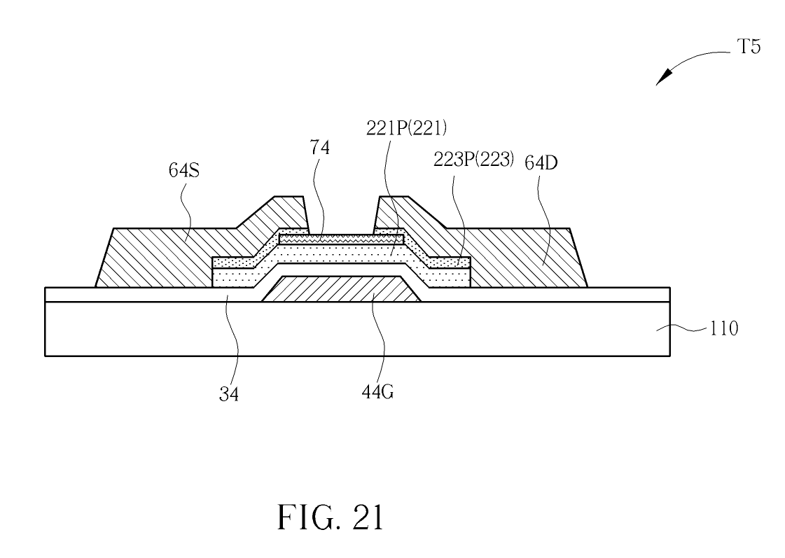

Please refer to FIG. 21. FIG. 21 is a schematic diagram illustrating a method of forming the thin film transistor according to a sixth preferred embodiment of the present invention. As shown in FIG. 21, the difference between the method of forming the thin film transistor in this embodiment and the method of the fifth preferred embodiment is that the method of forming the thin film transistor in this embodiment further includes forming an etching stop layer 74 on the semiconductor pattern 221P. In other words, the etching stop layer 74 is formed before forming the doped poly silicon layer 223, and the patterned doped layer 223P at least partially covers the etching stop layer 74. The etching stop layer 74 may be used to protect the semiconductor pattern 221P from being damaged during the process of forming the patterned doped layer 223P. The tolerance of process variations in the second patterning process may be accordingly enhanced, and an electrically performance of a thin film transistor T5 as shown in FIG. 21 may also be enhanced.

To summarize the above descriptions, in the present invention, the thin film silicon layer is formed on the substrate first, and the heating treatment is then performed to convert the thin film silicon layer into the thin film poly silicon layer by thermal annealing. The crystallization effect may be realized without laser annealing processes. The purposes of lowering manufacturing cost, enhancing manufacturing efficiency, and improving the uniformity of the thin film poly silicon layer on the large-sized substrate may be accordingly achieved. Additionally, the method of forming the thin film poly silicon layer in the present invention may also be applied in the method of forming the thin film transistor so as to simplify the related processes and lower the manufacturing cost.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of forming a thin film poly silicon layer, comprising:
providing a substrate;
performing a silicon thin film deposition process to form a thin film silicon layer on the substrate; and
applying a heating treatment to the substrate so as to convert the thin film silicon layer into a thin film poly silicon layer.

2. The method of claim 1, wherein a heating temperature of the heating treatment to the substrate is between 650 Celsius degrees and 700 Celsius degrees.

3. The method of claim 1, wherein the heating treatment comprises heating the substrate by a furnace device.

4. The method of claim 3, wherein the furnace device comprises a radio frequency (RF) heating source or an infrared (IR) heating source configured to heating the substrate.

5. The method of claim 1, wherein the silicon thin film deposition process comprises a chemical vapor deposition (CVD) process or a physical vapor deposition (PVD) process.

6. The method of claim 5, wherein the chemical vapor deposition process comprises a plasma enhanced chemical vapor deposition (PECVD) process, a metal-organic chemical vapor deposition (MOCVD) process, or a low pressure chemical vapor deposition (LPCVD) process.

7. The method of claim 1, wherein the thin film silicon layer is an amorphous silicon layer.

8. The method of claim 1, wherein the thin film silicon layer is a small crystal silicon layer and a grain size of the small crystal layer is smaller than 100 nm.

9. A method of forming a thin film transistor, comprising:
providing a substrate;
performing a silicon thin film deposition process to form a thin film silicon layer on the substrate;
applying a heating treatment to the substrate so as to convert the thin film silicon layer into a thin film poly silicon layer;
performing a first patterning process on the thin film poly silicon layer to form a semiconductor pattern;
forming a gate electrode;
forming a gate insulation layer; and
forming a source electrode and a drain electrode.

10. The method of claim 9, wherein a heating temperature of the heating treatment to the substrate is between 650 Celsius degrees and 700 Celsius degrees.

11. The method of claim 9, wherein the heating treatment comprises heating the substrate by a furnace device.

12. The method of claim 11, wherein the furnace device comprises a radio frequency (RF) heating source or an infrared (IR) heating source configured to heating the substrate.

13. The method of claim 9, wherein the silicon thin film deposition process comprises a physical vapor deposition (PVD) process a plasma enhanced chemical vapor deposition process, a metal-organic chemical vapor deposition process, or a low pressure chemical vapor deposition process.

14. The method of claim 9, wherein the gate insulation layer is formed after the first patterning process, and the gate electrode is formed after forming the gate insulation layer.

15. The method of claim 14, further comprising:
performing an ion implantation process to form a plurality of doped regions in the semiconductor pattern after forming the gate electrode;
forming a protection layer on the gate insulation layer and the gate electrode; and
forming a plurality of first openings in the protection layer and the gate insulation layer, wherein the first openings partially expose the doped regions, and the source electrode and the drain electrode contact the doped region via the first openings.

16. The method of claim 15, further comprising;
performing a thermal activation process after the ion implantation process, wherein the thermal activation process comprises a light heating approach, an ion beam heating approach, an electrode beam heating approach, a furnace heating approach, or a filament heating approach.

17. The method of claim 9, further comprising:
forming a doped silicon layer on the silicon layer by the silicon thin film deposition process, wherein the doped silicon layer is converted into a doped poly silicon layer after the heating treatment; and
performing a second patterning process on the doped poly silicon layer to form a patterned doped layer.

18. The method of claim 17, wherein the gate insulation layer is formed after the second patterning process, the gate insulation layer comprises a plurality of second openings partially exposing the patterned doped layer, and the source electrode and the drain electrode contact the doped region via the second openings.

19. The method of claim 18, wherein the gate electrode, the source electrode, and the drain electrode are formed after forming the gate insulation layer, and the gate electrode, the source electrode, and the drain electrode are formed by an identical process step.

20. The method of claim 17, wherein the patterned doped layer, the source electrode, and the drain electrode are formed by an identical process step, the gate insulation layer is formed after forming the source electrode and the drain electrode, and the gate insulation layer comprises a plurality of second openings partially exposing the source electrode and the drain electrode.

21. The method of claim 17, wherein the gate electrode and the gate insulation layer are formed before forming the thin film silicon layer and the doped silicon layer, and the source electrode and the drain electrode are formed after forming the thin film poly silicon layer and the doped poly silicon layer.

22. The method of claim 21, wherein the patterned doped layer, the source electrode, and the drain electrode are formed by an identical process step.

23. The method of claim 21, further comprising:
forming an etching stop layer on the semiconductor pattern, wherein the patterned doped layer at least partially covers the etching stop layer.

24. The method of claim 9, wherein the thin film silicon layer is an amorphous silicon layer.

25. The method of claim 9, wherein the thin film silicon layer is a small crystal silicon layer and a grain size of the small crystal layer is smaller than 100 nm.
